(19) United States
(12) Patent Application Publication
(10) Pub. No.: US 2014/0355095 A1
(43) Pub. Date: Dec. 4, 2014

(54) MULTI-PURPOSE OPTICAL CAP AND APPARATUS AND METHODS USEFUL IN CONJUNCTION THEREWITH

(71) Applicant: MARADIN TECHNOLOGIES LTD., Yoqne'am Ilit (IL)

(72) Inventors: Matan Naftali, Moshav Aloney-Aba (IL); Sharon Hornstein, Pardes Hanna (IL); Adi Baram, Yoqneam (IL); Menashe Yehiel, Moshav Yogev (IL)

(21) Appl. No.: 14/372,580

(22) PCT Filed: Jan. 16, 2013
(86) PCT No.: PCT/IL2013/050045

§ 371 Date: Jul. 16, 2014

Related U.S. Application Data
(60) Provisional application No. 61/586,847, filed on Jan. 16, 2012.

(51) Int. Cl. G02B 26/08; G02B 26/10; G02B 27/00; B81C 3/00

(52) U.S. Cl. CPC G02B 26/0833; B81C 3/008; G02B 26/105; G02B 27/0006
USPC 359/225.1; 438/51

(57) ABSTRACT

A method for protecting an optical MEMS device, including providing an optical MEMS device defining a field of view and including layers which define a main plane; and forming a protective element, constructed and operative for at least partly covering the optical MEMS device, from an optical structural material and wherein the protective element includes a planar portion tilted with respect to said main plane via which a majority of light energy directed toward said main plane must pass.

### REFERENCE TO CO-PENDING APPLICATIONS

Priority is claimed from U.S. provisional application No. 61/586,847, entitled “Tilted Optical Device For Reflection Manipulation” and filed 16 Jan. 2012.

### FIELD OF THIS DISCLOSURE

The present invention relates generally to optical devices and more particularly to MEMS-type optical devices.

### BACKGROUND FOR THIS DISCLOSURE

Many optical devices require an optical window, through which electromagnetic radiation may pass and interact with the device itself, such as:

| | |
|---|---|
| Fraunhofer | Paper: A novel vacuum-packaged low-power scanning |
| Institute for | mirror with inclined |
| Silicon | 3D-shape window |
| Texas | U.S. Pat. No. 6,762,868 B2 (2004) |
| Instruments Inc. | Electro-Optical package with Drop-in Aperture |
| Fraunhofer | US 2008/0239531 A1 Optical device comprising a |
| | structure for avoiding reflections |
| Gennum | U.S. Pat. No. 7,566,866 B2 (2009) |
| Corporation | System and methods for a tilted optical receiver |
| | assembly |
| Memphis Eye | US 2004/0190127 A1 |
| and Cataract | Digital micromirror device having a window |
| Assoc. | transparent to UV light |
| Maeda et al. | US 2009/0008669 A1 |
| | Package for micromirror device |
| Hitachi Ltd. | US 2008/0285914 A1 Optical module |
| Shellcase Ltd. | US 2005/0104179 A1 |
| | Methods and apparatus for packaging integrated circuit |
| | devices |
| Microvision Inc. | US 2008/0136742 A1 Method and apparatus for |
| | compensating for distortion in a scanned beam system |

This requirement raises challenges on packaging of such optical devices [Shellcase, US20050104179]. As packaging usually serves as a mechanical protection structure (e.g., dust prevention, avoidance of miss-handling etc.), and/or ensuring a certain operation environment (e.g., pressurized environment, gassed environment etc.) of the packaged device, in such optical devices the packaging also affects the optical performance, thus the functionality of the device itself.

The electromagnetic radiation being reflected from the optical window can be classified into two types, principal reflection and unwarranted reflection. Principal reflection is that part of radiation that is required for the functionality of the device. Unwarranted reflection is composed of primary and higher-order reflections that are created due to an imperfect functionality of the optical window, such as poor transparency of the optical window (e.g., optical insertion loss) due to its material or surface treatment. Unwarranted reflections might have a minor effect on some optical devices (e.g., sensors, such as photo-diodes, CCDs, etc.). However, they may have a significant influence on devices that are primarily designed to reflect radiation and project information (or signals) through the optical window (such as: DMD, scanning micro-mirrors, optical x-connectors etc.) for different uses. If unwarranted reflections appear on the same optical path created by the principal reflection, they can be interpreted as false signals emanating from the device or as optical noise, thus affecting its functionality and its proper operation.

Avoidance and/or reduction of such unwarranted reflections may be applied in various methods. A prevalent method of reducing reflections is by using Anti-Reflective-Coating (ARC) on the surfaces of the optical window. The use of ARC may result in greatly reduced unwarranted reflections [Fraunhofer, US20080239531], but not entirely. This may diminish the performance of such devices since even a small portion of the reflections may affect proper operation of the device.

An alternative solution is to use additional components outside of the package itself [Microvision, US20080136742], in order to manipulate the reflections such that they will not be directed on the desired optical path. Although this method, together with the use of ARC, could offer a good solution, it is more costly and requires additional space. In applications where cost and volume are limited, this solution is not feasible.

An additional method for manipulation of reflections without any use of additional components is by creating an angle between the optical window and the device itself [Gennum, U.S. Pat. No. 7,566,866], [Fraunhofer, US20080239531]. This is realized by positioning the optical device at an angle, which is measured between the device with respect to its substrate. This method simplifies the manufacturing and assembly of the protective structure, since the structure remains parallel to the substrate of the optical device and enables use of various manufacturing and/or assembly methods such as: wafer-level-packaging, pick and place assignment of discrete packaging etc.

MEMS-based mirrors are developed and manufactured e.g. by Texas Instruments (e.g. U.S. Pat. No. 6,762,868), Fraunhofer (e.g. US 2008/0239531 A1), and by Lemoptix.com.

Wafer-level packaging is known, e.g. in Fraunhofer, “A Novel Vacuum-Packaged Low-Power Scanning Mirror With Inclined 3d-Shaped Window”; and as described at the website of Lemoptix.com, at the following page: technology/innovation/mems-fabrication.

According to Wikipedia, “Wafer-level packaging (WLP) is the technology of packaging an integrated circuit at wafer level . . . extending the wafer fabrication processes to include device interconnection and device protection processes. Most other kinds of packaging does wafer dicing first, and then puts the individual die in a plastic package and attaches the solder bumps. Wafer-level packaging involves attaching the top and bottom outer layers of packaging, and the solder bumps, to integrated circuit while still in the wafer, and then wafer dicing. There is no single industry-standard method of wafer-level packaging at present.”

System level packaging is known and is described, for a Microvision micro-mirror, at the following http www location: amazon.com/MicroVision-SHOWWX-Classic-Laser-Projector/dp/B003G5ML9Y.

The disclosures of all publications and patent documents mentioned in the specification, and of the publications and patent documents cited therein directly or indirectly, are hereby incorporated by reference. Materiality of such publications and patent documents to patentability is not conceded.

The term “optical” may refer to any physical component of a system whose function includes affecting the path of electromagnetic radiation impinging on that body in a manner which serves the purpose of the system.

### SUMMARY OF CERTAIN EMBODIMENTS

Certain embodiments of the present invention are related to the field of optical devices in which unwarranted reflections of electromagnetic radiation (i.e., light beams) interacting with the devices are manipulated. More particularly, certain embodiments of the present invention relate to packaging of optical semi-conductor devices (also micro-electro-optical systems), which are packaged with a protective structure which has an optical window (i.e., optical aperture), and whose functionality may be affected by unwarranted reflections of light, interacting with the optical window structure of such devices.

Certain embodiments of the present invention seek to provide a new paradigm in packaging of optical devices. This invention shows an efficient way to manipulate unwarranted reflections using a simple implementation method for such.

Certain embodiments of the present invention seek to provide novel optically designed packaging, for manipulating unwarranted reflections from optical windows. This novel architecture provides new performance with respect to known state-of-the-art solutions while reducing the dimensions and cost of such packaging, and enhancing the performance of the optical device itself.

A light beam interacts with a surface in a certain point, creates reflections according to its angle of incidence and the surface itself. If the angle of incidence is smaller than the critical angle of the surface, most of the light will pass into the medium of the surface (according to Snell's law), but a fraction of its energy will be reflected back, according to the reflectivity of the surface.

Certain embodiments of the present invention seek to provide a method of manipulating these reflections, by creating a tilted surface of the optical window, on the protective structure.

Certain embodiments of the present invention seek to provide a new paradigm in packaging of optical devices while reducing the dimensions and cost of such packaging, and enhancing the performance of the optical device itself.

Certain embodiments of the present invention seek to provide a system simultaneously operative for protecting an optical device upon which a light beam (visible or non-visible) impinges, thereby to define a light path, and manipulating unwarranted radiation e.g. reflections from interaction of a light beam and the optical window of the device's package. Typically, most of the light will pass into the medium of the surface (according to Snell's law), but a fraction of its energy, whose size depends on the reflectivity of the surface, will be reflected back.

There is thus provided, in accordance with some preferred embodiments of the present invention, a method of protecting an optical device, along with manipulating unwarranted reflections from the interaction of a light beam and the optical window of the device's package. This method comprises:
a) An optical device that, for its functionality, needs a path of light beam (visible or non-visible), that impinges onto the device.
b) A tilted optical window, as part of the protective structure of the device that is placed or manufactured on top of the optical device.
c) A tilted optical window with or without Anti Reflective Coating (ARC) on its optical surfaces.

Typically, a tilted optical window is provided e.g. for manipulating such reflections, and the window is integrally formed with a protective structure placed or manufactured atop the optical device. The tilted optical window may optionally have Anti Reflective Coating (ARC) on some or all of its optical surfaces.

To manufacture the protective structure with its tilted optical window, any suitable methods may be employed such as but not limited to: wafer level packaging techniques, plastic molding, or fine machinery, depending e.g. on the material from which the optical window is formed (e.g. Glass, Silicon, Germanium, plastic such as, say, Makrolon 2405 (polycarbonate), or other) and on the functionality of the optical window. For example, plastic molding may be used when an optical window is assembled atop a micro-scanning mirror according to certain embodiments of the present invention, because plastic molding facilitates simple and cost effective manufacturing of tilted surfaces with high accuracy and optical grade.

To assemble the protective structure with its tilted optical window, any suitable methods may be employed, e.g. depending on the manufacturing method used to create the protective structure, such as but not limited to: wafer to wafer bonding (if the protective structure is created at wafer level), or pick and place.

The present invention typically includes at least the following embodiments:

Embodiment 1: An optical tilted protective structure that is being placed or manufactured on top of or adjacent to an optical device.

Embodiment 2. The device of Embodiment 1 that has a tilted optical surface, serves as an optical window (or aperture), through which an electromagnetic radiation passes to the optical device.

Embodiment 3. The device of Embodiment 1 that has a tilted optical surface, through which an electromagnetic radiation passes back and forth from the optical device.

Embodiment 4. The device of Embodiment 1 that has a tilted optical surface, through which an electromagnetic radiation passes back and forth from the optical device, and this aperture could be covered with an anti-reflecting-coating on at least one side.

Embodiment 5. The device of Embodiment 1 that has a tilted optical surface that is formed of different materials such as: plastic; glass; Silicon; Germanium etc, according to the wavelength required for the functionality of the optical device.

Embodiment 6. The device of Embodiment 1 that has a tilted optical surface that is formed by different methods such as: plastic molding; fine machining process etc.

Embodiment 7. The device of Embodiment 6 that has a tilted optical surface that is assembled to the optical device by different methods such as: manual assembly; pick and place processes; wafer-level-packaging processes etc.

Embodiment 8. The device of Embodiment 1 that serves also as a protective structure for the optical device itself, forming a cavity between the device of claim 1 and the optical device structure.

Embodiment 9. The device of Embodiment 8 that allows a free motion of the optical device in the cavity formed between the device of claim 8 and the optical device structure.

Embodiment 10. The device of Embodiment 1 that has a tilted optical surface such that the principal reflection from its surface is projected in its desired direction.

Embodiment 11. The device of Embodiment 1 that has a tilted optical surface such that the unwarranted reflections from its surface are reflected to a different angle than the principal reflections.

Embodiment 12. The device of Embodiment 1 that has tilted optical surfaces which are parallel such that these surfaces deflect the principal reflection from the optical device only in a lateral direction and maintain the same direction.

In accordance with an aspect of the presently disclosed subject matter, there is provided

a method for protecting an optical MEMS device, including:

providing an optical MEMS device, including a micro-mirror, defining a field of view and including layers which define a main plane; and

forming a protective element, constructed and operative for at least partly covering the optical MEMS device, from an optical structural material and wherein the protective element includes a planar portion tilted with respect to the main plane via which a majority of light energy directed toward the main plane must pass,

wherein the protective element also defines a top planar surface parallel to the main plane and wherein the planar portion tilted with respect to the main plane is disposed intermediate the main plane and the top planar surface.

In accordance with an embodiment of the presently disclosed subject matter, there is further provided a method wherein the protective element is configured and oriented to complete an enclosure sealing off the optical MEMS device relative to the environment.

In accordance with an embodiment of the presently disclosed subject matter, there is yet further provided a method comprising placing the protective element adjacent to the optical device, subsequent to the forming.

In accordance with an embodiment of the presently disclosed subject matter, there is yet further provided a method wherein:

presence of the protective element results in unwarranted reflection when the optical MEMS device is illuminated with electromagnetic radiation; and wherein the providing a protective element comprises selecting, for the planar portion, a tilt angle, relative to the first main plane, which prevents the unwarranted reflection from entering the field of view.

In accordance with an embodiment of the presently disclosed subject matter, there is yet further provided a method wherein the electromagnetic radiation is provided by a coherent light source.

In accordance with an embodiment of the presently disclosed subject matter, there is yet further provided a system for protecting an optical MEMS device, including:

an optical MEMS device, including a micro-mirror, defining a field of view and including layers which define a main plane; and

a protective element, constructed and operative for at least partly covering the optical MEMS device, from an optical structural material and wherein the protective element includes a planar portion tilted with respect to the main plane via which a majority of light energy directed toward the main plane must pass,

wherein the protective element also defines a top planar surface parallel to the main plane and wherein the planar portion tilted with respect to the main plane is disposed intermediate the main plane and the top planar surface.

In accordance with an embodiment of the presently disclosed subject matter, there is yet further provided a method wherein the optical MEMS device is oriented such that its main plane is horizontal and wherein the forming is performed atop the optical device.

In accordance with an embodiment of the presently disclosed subject matter, there is yet further provided a system wherein the top planar surface at least partly surrounds the planar portion tilted with respect to the first main plane.

In accordance with an embodiment of the presently disclosed subject matter, there is yet further provided a system wherein coherent electromagnetic radiation impinges upon the main plane thereby to define a first axis and wherein the planar portion is tilted with respect to the main plane, along a second axis perpendicular to the first axis.

In accordance with an embodiment of the presently disclosed subject matter, there is yet further provided a method comprising applying a vacuum tip to the top planar surface parallel to the main plane.

In accordance with an embodiment of the presently disclosed subject matter, there is yet further provided a method wherein the optical MEMS device is operative to project signals, representing information, through an optical window formed by the protective element.

In accordance with an embodiment of the presently disclosed subject matter, there is yet further provided a method wherein the micro-mirror comprises a digital mirror moving between first and second orientations.

In accordance with an embodiment of the presently disclosed subject matter, there is yet further provided a method wherein the micro-mirror comprises a scanning micro-mirror.

In accordance with an embodiment of the presently disclosed subject matter, there is yet further provided a method wherein the micro-mirror comprises an analog mirror operative for continuous motion.

In accordance with an embodiment of the presently disclosed subject matter, there is yet further provided a system wherein the protective element also includes a bottom planar surface attached to the MEMS device.

In accordance with an embodiment of the presently disclosed subject matter, there is yet further provided a system wherein the protective element comprises a one-piece optical element.

In accordance with an aspect of the presently disclosed subject matter, there is yet further provided a method for protecting an optical MEMS device, including:

providing an optical MEMS device, including a micro-mirror, defining a field of view and including layers which define a main plane; and

forming a protective element, constructed and operative for at least partly covering the optical MEMS device, from an optical structural material and wherein the protective element includes a planar portion tilted with respect to the main plane via which a majority of light energy directed toward the main plane must pass,

wherein the protective element comprises a one-piece optical element.

In accordance with an embodiment of the presently disclosed subject matter, there is yet further provided a method wherein a plurality of protective elements are manufactured one-by-one and then assembled one-by-one on a corresponding plurality of dies.

In accordance with an embodiment of the presently disclosed subject matter, there is yet further provided a method wherein the device is formed from a die having a main plane, the method also comprising die level (MEMS) packaging by:

dicing the die;

moving the die to an assembly stage where internal components are assembled; and moving the die to a packaging stage, where an optical cap is attached to the die's main plane.

The embodiments referred to above, and other embodiments, are described in detail in the next section.

Any trademark occurring in the text or drawings is the property of its owner and occurs herein merely to explain or illustrate one example of how an embodiment of the invention may be implemented.

Elements separately listed herein need not be distinct components and alternatively may be the same structure.

Any suitable processor may be employed to control manufacturing or operating processes, or compute or generate information therefor, e.g. by providing one or more modules in the processor to control functionalities described herein. Any suitable computerized data storage e.g. computer memory may be used to store information received by or generated by the systems shown and described herein. Functionalities shown and described herein may be divided between a server computer and a plurality of client computers. These or any other computerized components shown and described herein may communicate between themselves via a suitable computer network.

### BRIEF DESCRIPTION OF THE DRAWINGS

Certain embodiments of the present invention are illustrated in the following drawings:

FIG. 1 is an isometric view of an optical tilted protective structure atop a substrate including an optical device to be protected, in accordance with certain embodiments of the present invention.

FIG. 2a is a side view illustration of the apparatus of FIG. 1, in accordance with certain embodiments of the present invention.

FIG. 2b is a cross sectional view of the apparatus of FIGS. 1-2a, in an example embodiment in which the optical device to be protected comprises a scanning micro-mirror, all in accordance with certain embodiments of the present invention.

FIG. 2c is an isometric partially cut-away view of an optical tilted protective structure (“optical cap”) atop a scanning micro-mirror, in accordance with certain embodiments of the present invention.

FIG. 2d is a detailed view of the bubble shown in FIG. 2c.

FIG. 2e illustrates a different position of the apparatus as opposed to FIGS. 2c-2d, due to out-of-plane motion of the device provided in accordance with certain embodiments of the present invention.

FIG. 3 is a diagram of an optical simulation, presenting lateral deflection of the principal reflections from the optical device, through the tilted optical protective structure surface, in accordance with certain embodiments of the present invention.

FIG. 4 is a diagram of an optical simulation, presenting the deflected unwarranted reflections from the tilted optical protective structure surface, in accordance with certain embodiments of the present invention.

FIG. 5 is a simplified flowchart illustration of a manufacturing process, useful in accordance with certain embodiments of the present invention, of a MEMS-based micro mirror system including the optical cap shown and described herein, which is assembled at the “cap assembly” stage 430. The method of FIG. 5 typically comprises some or all of the illustrated steps, suitably ordered e.g. as shown.

FIG. 6a is a 2D top view illustration of the field of view, indicating various optical and geometrical parameters.

FIG. 6b is a 3D view illustration of a protective element having a parallel top surface showing including the offset of the reflected laser spot from the cap surface. As shown, the reflection of the laser, spot 310, is located inside the field of view.

FIG. 6c is a 3D view of a protective element having a tilted surface and, as shown and in contrast to FIG. 6b, the reflection of the laser is a spot 310 located outside the field of view, with vertical offset between the spot 310 and the horizontal axis of the field of view.

FIG. 6d shows the advantageousness of a symmetrical design of the protective element, in accordance with certain embodiments of the present invention, in that a projected image may be produced on a selected side of the normal to the mirror, depending, say, on obstructions which may be present on one or another of the sides.

FIG. 6e is a table which defines angles shown in FIG. 6a.

FIG. 7 is a simplified flowchart illustration of a pick-and-place method, useful in accordance with certain embodiments of the present invention, in which a vacuum tip may hold a single protective element. After attachment to the MEMS die, the MEMS and its protective element may be separated and managed using a vacuum tip, which is advantageous since it is very difficult to handle the MEMS dies without any protective cover, due to their small size and fragile axes. The method of FIG. 7 typically comprises some or all of the illustrated steps, suitably ordered e.g. as shown.

FIG. 8 is an exploded view of the apparatus of FIG. 1, in accordance with certain embodiments of the present invention.

FIG. 9 is a simplified flowchart illustration of a Die level (MEMS) packaging method useful in accordance with certain embodiments of the present invention.

### DETAILED DESCRIPTION OF CERTAIN EMBODIMENTS

According to certain embodiments, a tilted optical window in a protective structure is provided. A light beam impinges on the surface of the optical window, and passes through it until it interacts with the optical device located underneath. While most of the radiation penetrates through the optical window, a fraction of its energy is reflected from the tilted surface. The direction of the reflected radiation is determined according to the angle of the tilted optical window, in a way such that it is directed to a certain direction which does not affect proper operation of the device. The angle of the inclined surface of the optical window is designed such that it will be smaller than the critical angle of the light, and by that most of the energy will be passing through the optical window. By using ARC, according to the desired wavelength of the electromagnetic radiation, the fraction of the energy reflected is reduced dramatically. Such ARC could be implemented on both sides (i.e., surfaces) of the tilted optical window.

According to Snell's law, when a light beam passes from one medium to the other (e.g., from air to plastic or vice versa), its direction is changed according to the material properties of the medium. Moreover, if the radiation passes through the medium both in its entry and in its exit directions, the change in its direction on the way back is dictated by the angles of the medium surfaces as well as the medium properties. In the general case, the two angles that create the tilted surfaces can be different, such that the surfaces are not parallel to one another. In such a case, the change in the direction of the radiation, measured between the initial direction before entry to the medium and the final one (after the beam exit from the medium), can be calculated directly from the difference in the two surfaces' angles.

When the tilted surfaces in the optical window are parallel, e.g. by designing the optical window such that its two surfaces are tilted at the same angle with respect to the optical device located underneath, the overall change of the reflected radiation from the tilted window is only in the lateral direction, with a constant difference in the direction of the reflected beam with respect to the initial beam. As the light beam passes from one medium to another and then back to the original medium, the overall direction change according to Snell's law will be only in the lateral direction, and the direction of the light beam will remain unchanged.

Moreover, a parallel structure of the inclined surfaces also enables the manipulation of secondary reflections from the bottom (secondary) surface of the inclined optical window. As long as the tilt angle is identical to the first (primary) surface, the secondary reflections will be redirected to the same direction as the primary unwarranted ones.

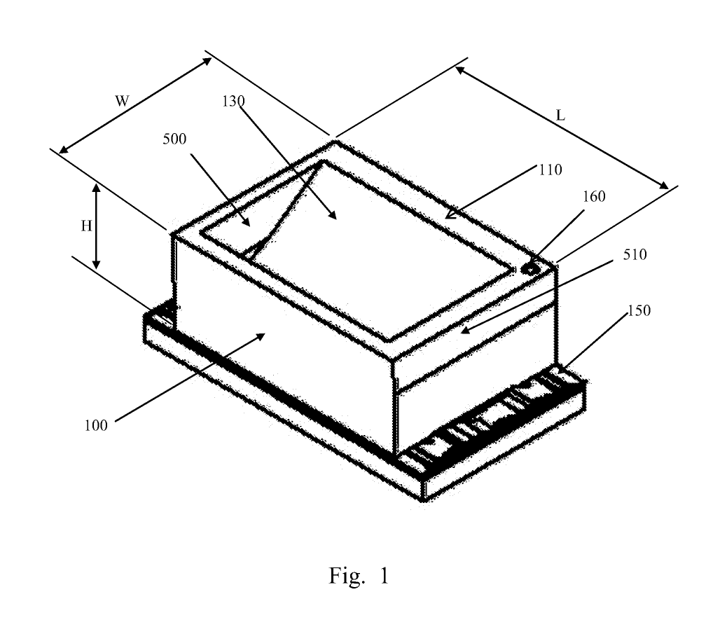

Manufacturing of the protective structure, comprising of the tilted optical window, may be done using various methods, such as, but not limited to: usage of wafer level packaging techniques, plastic molding, fine machinery etc., according to the material used for the optical window and its functionality. In addition, the optical window may be made of various materials, such as: glass, silicon, germanium, plastic etc. As an example, and not affecting the general case, a plastic molding may be used for a case in which an optical window is assembled on top of a micro-scanning mirror, as illustrated in FIG. 1. The use of plastic molding enables a simple and cost effective method of manufacturing tilted surfaces with high accuracy and optical grade.

The assembly of the protective structure, comprising the tilted optical window, may also be carried out by various techniques, according to the manufacturing method used to create the protective structure. These methods include, but are not limited to: wafer to wafer bonding (in case of creating the protective structure in a wafer level), assembly using pick and place equipment (in case of creating the protective structure in plastic molding, each structure separately) etc., according to the needs of a particular use case.

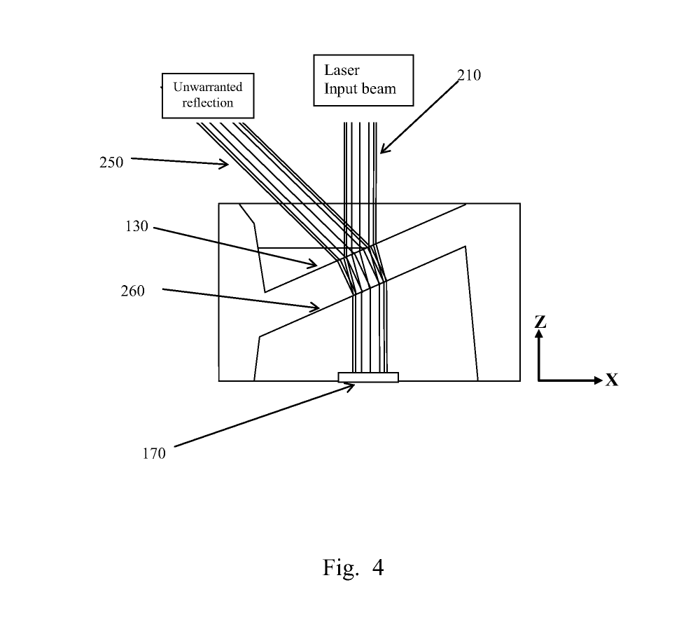

Reference is now made to FIG. 1 which is an isometric view of an optical protective structural element 100 atop a planar substrate e.g. MEMS layer/s having a main plane 150 and including an optical MEMS sub-assembly 140 to be protected. Typically, a population of MEMS sub-assemblies 140 is formed from the MEMS layer/s which are subsequently diced to yield individual MEMS sub-assemblies. Typically, the protective element is constructed and operative for at least partly covering the optical MEMS device, and may be configured and oriented to complete an enclosure sealing off the optical MEMS device relative to the environment. For example, the protective element may, together with a lower MEMS layer and the extension of the planar substrate 150, form an enclosed volume (e.g. as shown in FIG. 4) thereby sealing off the optical MEMS device relative to the environment. Typically, the protective element 100 is formed from an optical structural material such as glass and includes a planar portion e.g. tilted surface 130 which is tilted with respect to main plane 150 via which a majority of or all light energy directed toward main plane 150, typically including electromagnetic radiation provided by a coherent light source, must pass.

The “walls” extending down from top surface 110 may, if desired, be formed of sections or portions which may be differently inclined and/or of various different widths e.g. inclined wall portion 500 which may be provided to allow a larger reflection angle to be employed; and/or inclined wall portion 510 to facilitate removal of the protective element from the mold.

Typically although not necessarily, an alignment mark 160 is provided to facilitate automatic assembly processes in which components are aligned relatively to specific points or reference geometries. For example, when the protective element is taken up by the vacuum tip, the protective element's orientation may thus be determined with respect to the orientation of the mirror because the alignment mark 160 on the protective element corner effectively defines a specific orientation of the element, for a machine to use prior to assembly.

It is appreciated that according to the application, the tilted surface may be designed to tilt down from any of the “walls” extending down from top surface 110, depending, for example, on whether it is desired that unwarranted reflections be deflected to one side of the device rather than on the other.

Typically, the optical protective element does not cover the whole area of the MEMS die, e.g. if the external portions of the die are kept uncovered for electrical bondings performed later in the process. However, if electrical bondings between the pads to an external PCB are performed first, the optical cap may be applied atop the entire surface of the die.

Typically, the optical cap's external dimensions are driven by the dimensions of the optical MEMS device, e.g. from the dimensions of a micro-mirror and a gimbal providing 1-2 degrees of freedom of rotation to the mirror.

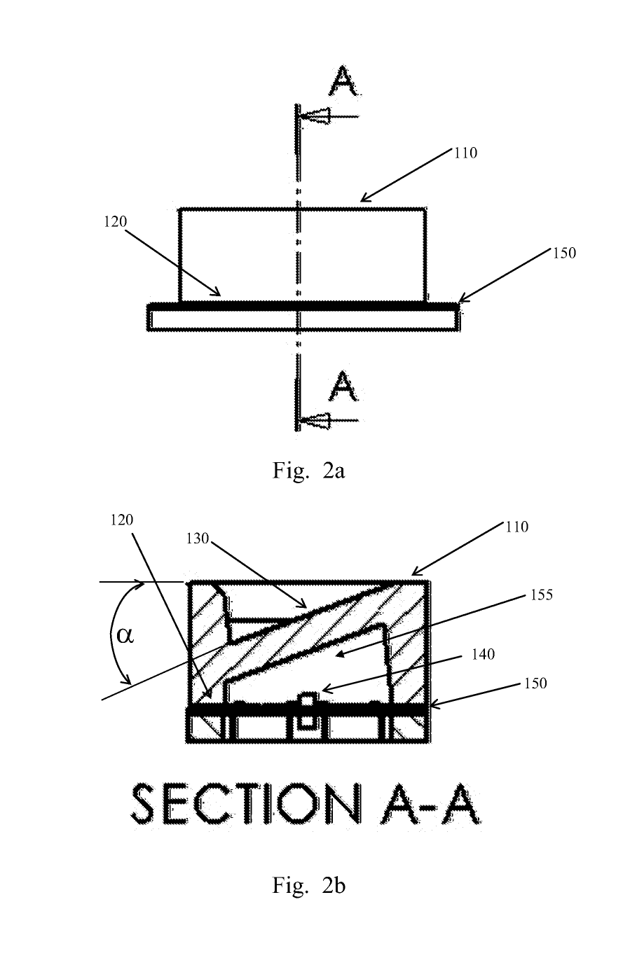

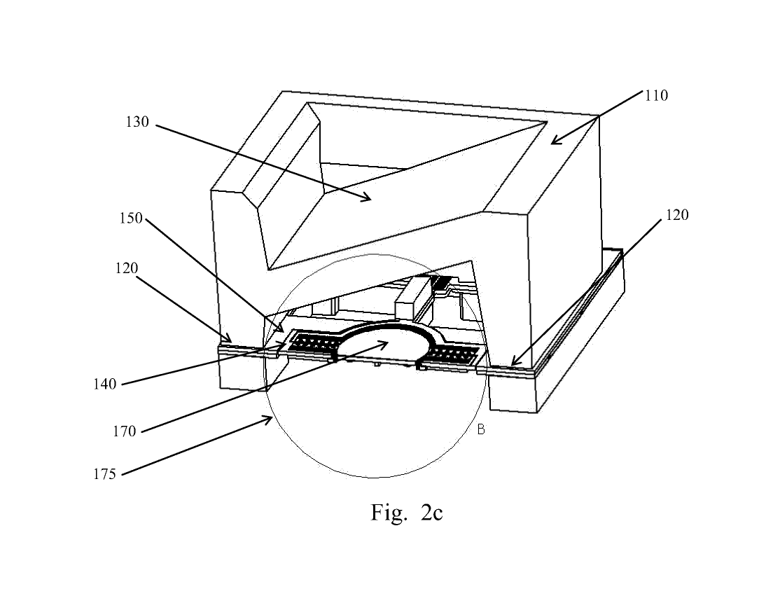

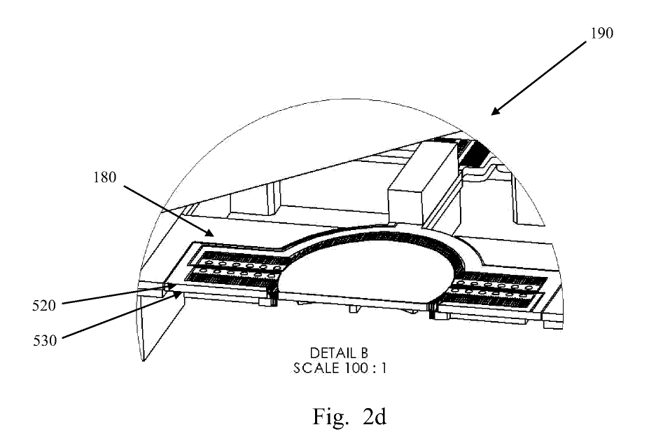

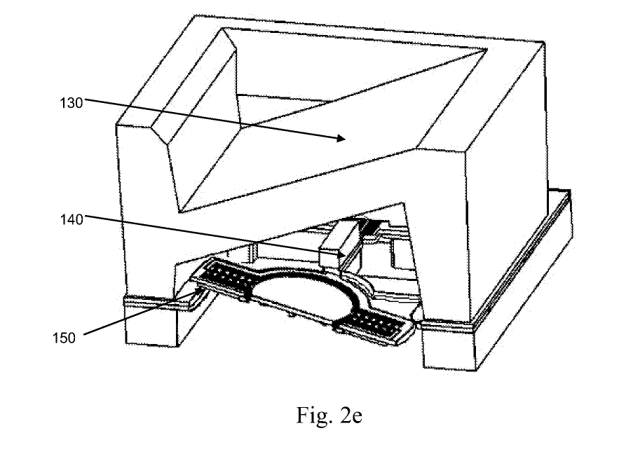

FIG. 2a is a side view illustration of the apparatus of FIG. 1 including a top surface 110 that is parallel to the bottom surface 120 of the substrate 150 such that a vacuum tip or other lifting device interacting with the MEMS device and its cover, has a suitably oriented surface to interact with. As shown, the top surface 110 may be peripheral to e.g. surround the tilted surface 130, either entirely as shown, or partly (e.g. if the four “walls” whose tops form top surface 110 were replaced by only 2, 3 or 3.5 such walls). Typically, tilted planar portion 130 is disposed intermediate to main plane 150 and top planar surface 110. Typically, the peripheral top surface 110 is large enough to be handled in an automatic assembly process using a vacuum tip.

FIG. 2b is a cross sectional view of apparatus similar to the apparatus of FIGS. 1-2a, in an example embodiment in which the optical device to be protected may include a scanning micro-mirror and/or a MEMS sub-assembly 140. As shown, the mirror's optical cap includes a top surface 110 that is parallel to the main plane 150 and a bottom surface 120 that is attached to the substrate surface 150. The tilted surface 130 is intermediate the two. Top surface 110 and bottom surface 120 are typically parallel to each other. Typically, as shown, the protective element or optical cap is configured and oriented to complete an enclosure or cavity 155, sealing off the optical MEMS device relative to the environment.

FIG. 2c is an isometric partially cut-away view of an optical tilted protective structure (“optical cap”) atop a scanning micro-mirror. As shown, the mirror's optical cap includes a top surface 110 that is typically parallel to the main plane of the substrate surface 150, a bottom surface that is typically bonded e.g. glued to the substrate surface 150, and a tilted surface 130 intermediate the two. As shown, the scanning micro-mirror may comprise a rotating mirror 170 forming part of a MEMS subassembly 140.

FIG. 2d is a detailed view of the bubble 175 shown in FIG. 2c, including x and y axes of rotation, 180 and 190 respectively, of the rotating mirror. It is appreciated that typically although not necessarily, a MEMS die is provided, having a top layer (mirror layer) 520 and a bottom layer 530.

Regarding the tilted surface, if the device is designed to have out-of-plane motion, e.g. as shown by comparison of FIGS. 2c-2d and 2e, then, as shown e.g. in FIG. 2b or 2c, the tilted surface typically does not extend all the way down to the bottom surface of the “frame” extending down from top surface 110. Instead, the tilted surface typically terminates at a point spaced from the main plane 150 to facilitate out-of-plane motion of, e.g. a gimbal, when torsional motion around the vertical axis 190 is desired. However, if the device (e.g. mirror) is a single-axis mirror, with only one axis of motion (say, the horizontal axis 180), the space may be reduced or eliminated.

Limiting factors for the tilt angle, alpha, may include: at the lower end, the angle may be large enough to divert unwarranted reflection away from the field of view. The field of view of a projector typically refers to the size of a projected image on a flat medium having horizontal and vertical sides. In laser-projectors, the field of view is affected by the normal distance between the projector and medium. If a too-small angle is selected, reflection from the top surface of the cap may be insufficiently diverted such that this unwarranted reflection may still be projected inside the field of view. At the upper range, the tilt angle may be small enough to avoid dispersion of light since there may be losses in terms of electromagnetic radiation when the beam impinges the cap medium at too-large angles.

For example, for a mirror of dimensions 3.55[mm] (width) and 6[mm] (length) and an optical cap of dimensions W=3.55[mm] (width), L=4.8[mm] (length), H=1.8[mm] (height), and a tilted surface whose lowest point is spaced approximately 360[micron] from the main plane 150, the values of the tilt angle, alpha, may be in the range of (8 [deg]-30 [deg]).

The tilted surface may be curved rather than planar as shown, e.g. if it is optically designed as a lens. The lens can be scattering or focusing depending on the application, which can obviate yet another separate component in a given system.

The protective element may be manufactured using an injection mold. Therefore, one possible material for the optical cap is Makrolon 2405 (Polycarbonate) which is transparent and is suitable for injection molding e.g. in terms of easy flow/viscosity enabling production of molding with thin walls. Other materials are also possible, e.g. materials used for optics applications such as ZEONEX (trademark)-Cyclo Olefin Polymer (COP), also used for creating optical components for cameras and laser beam printers.

The frame 110 of the protective element (also termed “optical cap”) is typically closed e.g. rectangular as shown, or any other circular or polygonal closed shape, to facilitate use of a vacuum for lifting of the element. Instead of having a single frame, the optical cap may even have a honeycomb-like configuration, with walls around each of an array of polygons e.g. hexagons and a tilted surface inside each hexagon or other polygon. Any closed geometric shape/s may be employed, however, since the protective element is going to be placed on top of a MEMS die, it is most likely that shape/s are derived from the shape of the die e.g. squares\rectangles due to dicing processes limited to straight lines.

Typically, the cap is designed to withstand a known vacuum level e.g. higher than 10̂(−2) Torr, e.g. by suitable selection of geometry including thickness of the frame walls. Also, the walls of the frame are thick enough to provide structural strength despite the limited strength of the material used. e.g. between 100[micro-meter]-1 mm, such as widths in the range of 250-500[micro-meter]; the frame need not have a uniform width throughout.

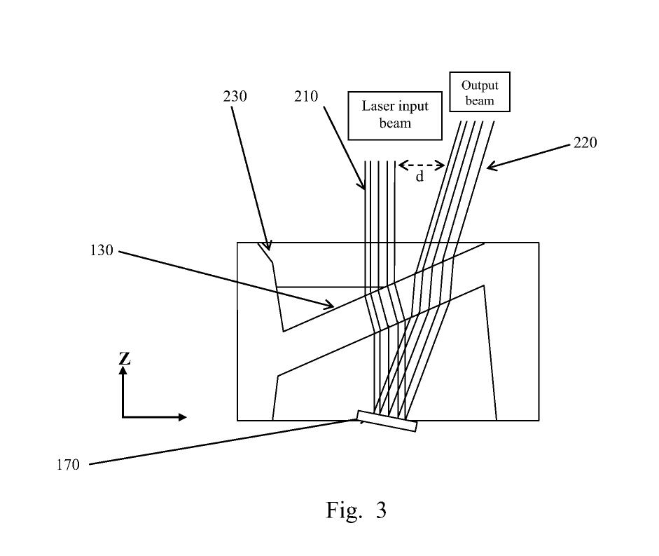

FIG. 3 is a diagram of an optical simulation, presenting lateral deflection of principal reflections (output beam) 220, of a laser beam 210 impinging on an optical device, through the tilted surface of an optical cap in accordance with embodiments of the present invention. Typically, a truncated surface 230 is provided inside the cap to allow a larger primary reflection angle from the mirror. The extent of the lateral deflection determines the distance d between the laser input 210 and the primary reflection 220 from the mirror.

FIG. 4 is a diagram of an optical simulation, presenting deflected unwarranted reflections of an input laser beam 210 from the tilted surface of an optical cap in accordance with embodiments of the present invention. Reference numeral 250 denotes reflection of the laser beam 210 from the bottom surface 260 of the tilted plane.

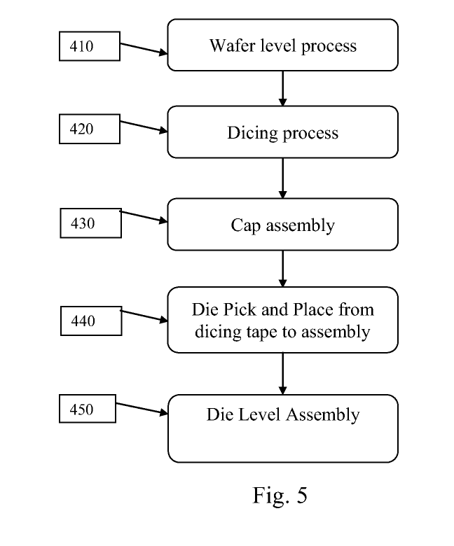

Referring now to FIG. 5, according to certain embodiments, protective elements are manufactured one-by-one and then assembled one-by-one on each die. FIG. 5 depicts a manufacturing process of a MEMS-based micro mirror with the optical cap shown and described herein, the process including some or all of the following steps, which may be performed in any suitable order e.g. as shown:

Step 410—wafer level process (each part required for the MEMS to be functional)

Step 420—Dicing process in which dies are cut but remain on the wafer, e.g. for processes that use coordinates for the assembly process

Step 430—Cap Assembly—may be performed when the dies are on a dicing tape. The caps are typically assembled one by one on each die.

Step 440—Pick and Place of die, from Dicing tape to assembly. After a cap is attached to each of the dies, each die, with its attached optical cap, may be automatically and individually moved from the tape on to the remaining steps of the assembly process.

Step 450—Die Level Assembly in which the dies are assembled one by one.

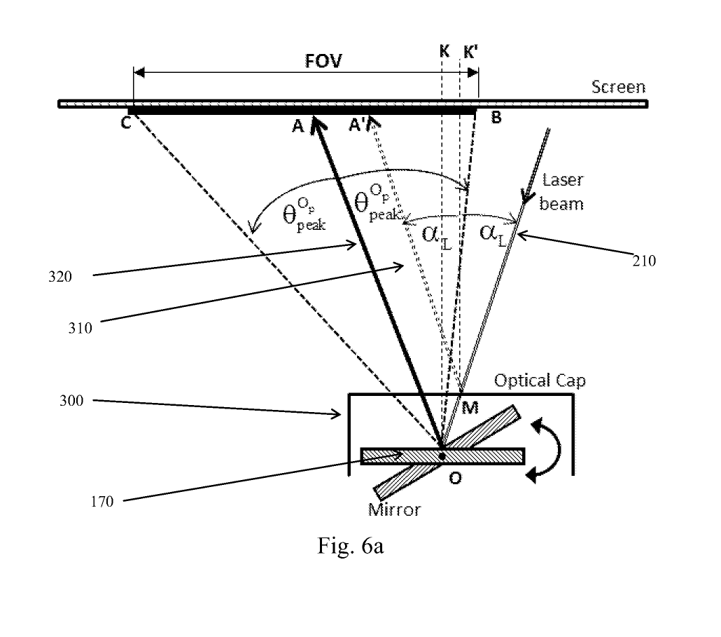

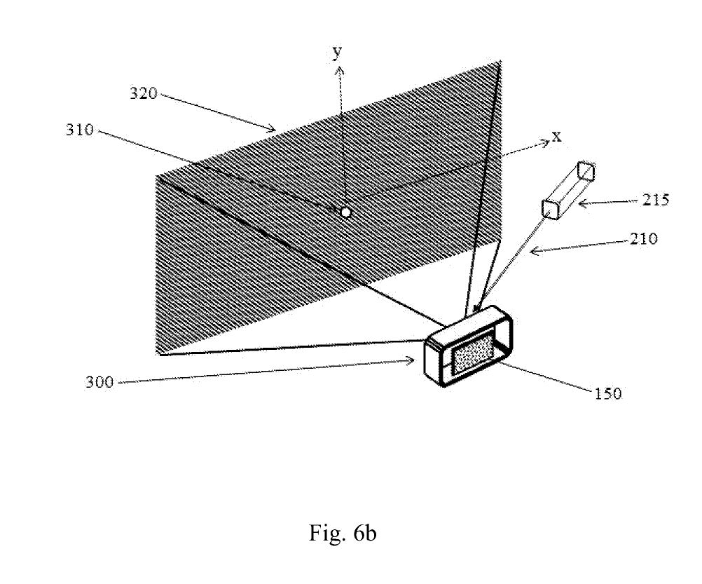

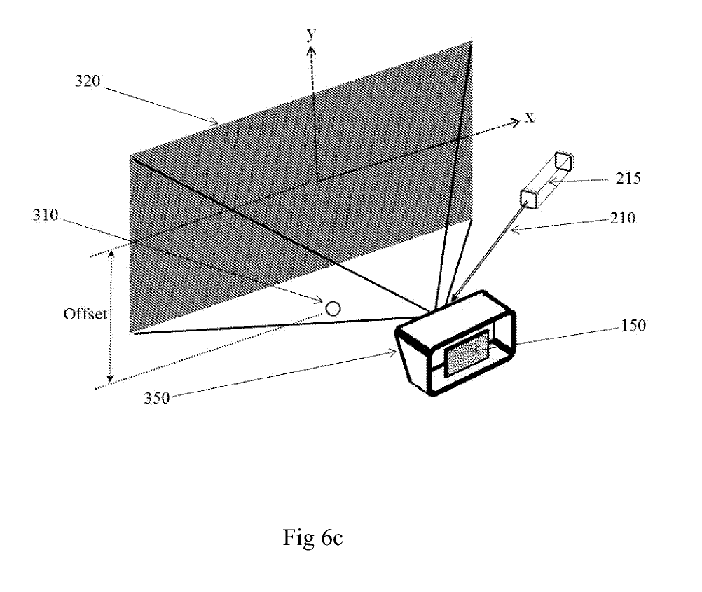

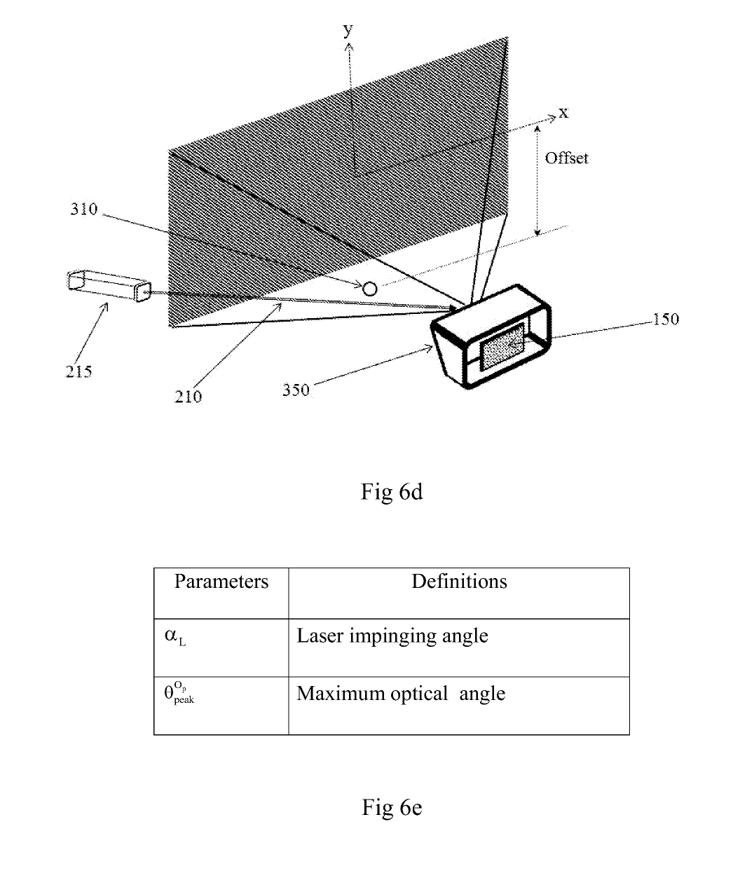

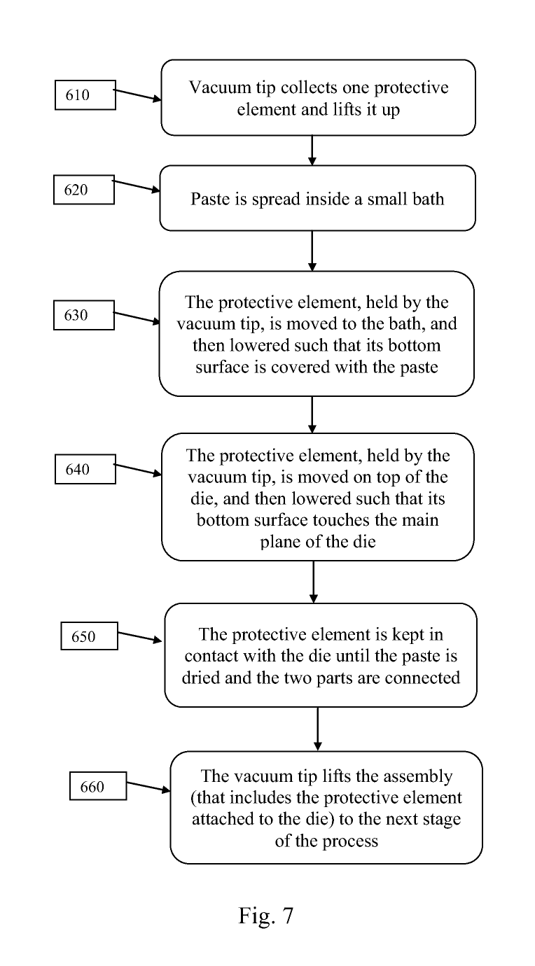

FIG. 6a is a simplified 2D top schematic view of the Field of View (FOV) of the optical device of FIGS. 1-4, showing that unwarranted electromagnetic radiation 310, e.g. reflection of the laser from the optical cap 300, may be present in the Field of View if the optical cap 300 is parallel to the mirror (say) plane contrary to the teachings of certain embodiments of the present invention. The principal reflection 320 of the laser from the mirror 170 is also present in the FOV, but this is of course desirable.

FIG. 6b is a simplified 3D schematic view of a Field of View of the optical device of FIGS. 1-4, showing that an optical cap 300 having a parallel top surface yields an undesired location, inside the field of view (FOV), of the laser spot 310 reflected from the cap surface.

FIG. 6c is a simplified 3D schematic view of a Field of View (FOV) of the optical device of FIGS. 1-4, showing that unwarranted electromagnetic radiation 310 e.g. reflection of the laser from the optical cap is, advantageously, absent from the FOV if the optical cap defines a tilted surface 350 relative to the mirror (say) plane in accordance with certain embodiments of the present invention. The principal reflection 320 of the laser from the mirror 170 is present in the FOV, which is of course desirable.

In FIG. 6a, the following notation is employed:
Point O—mirror's center point
Point A—projected laser beam spot from the mirror, when the mirror is at rest.
Point B—projected laser beam spot when the mirror is at its maximal rotation angle to the right.
Point C—projected laser beam spot when the mirror is at its maximal rotation angle to the left.
Point A′—projected laser beam spot as reflected from the optical cap.
KO—a normal to the mirror surface passing through the mirror's center point, when the mirror is at rest.
K′M—a normal to the optical cap's upper surface.

The table of FIG. 6e defines angles shown in FIG. 6a.

The horizontal distance between points B, C defines the horizontal field of view. It is appreciated that Point A′, representing unwarranted reflection of the laser beam from the cap, is located inside the field of view in FIG. 6a, but outside the field of view in FIG. 6c, which is an advantage of certain embodiments of the present invention.

In FIG. 6a the optical cap is parallel to the die's main plane, so the reflection from the optical cap's top surface is inside the field of view. In contrast, in FIG. 6c, the cap has a tilted surface as described in detail below.

In FIG. 6a, “principal” reflections are indicated in a thick solid line (line OA) and thick dashed-lines (lines OB and OC) whereas “unwarranted” reflections are indicated in a thin doubled-dashed lines (line OA′). Generally, principal reflection refers to a desired outcome of operation of a system designed a priori to reflect projected radiation for various specific purposes. For example, in image projectors such as pico-projectors which utilize rotating mirrors, the principal reflection is that projected from the rotating mirror. When the mirror rotates, a single light source that hits the mirror creates a 2D image on a screen. The 2D image that is projected from the mirror, then, constitutes principal reflection. Other examples of principal reflection: Head Up Display (HUD) systems, in which the system presents information (e.g., for a vehicle: speed, fuel, temperature information) on a screen or on an internal surface of a car's window. In contrast, unwarranted reflection is an outcome of radiation that is reflected from other surfaces or objects in the system e.g. from the protective medium that covers the mirror.

According to certain embodiments, the tilt angle is selected to be large enough to offset or deflect the reflected spot (e.g. 310, 311 in FIGS. 6b, 6c respectively) outside the field of view, depending on the mechanical deflection angle of the mirror that spans the vertical extent of the field of view (y axis in FIGS. 6b, 6c). For example, if maximal deflection of the y axis of a rotating mirror is 7.5[deg]. the tilt angle is larger e.g. may be 8 degrees, or 20 degrees as shown, as opposed to 0 degrees in FIG. 6a. The maximum value of the tilt angle is typically limited to reduce optical losses of the laser beam which occur if the angle of impingement upon the surface of the protective element is too high.

FIG. 6d is similar to FIG. 6c and is useful in applications in which another system component or other impediment impedes projection to one direction or another by a projection system e.g. pico-projector including the optical cap shown and described herein. As shown, a symmetrical design of the protective element is advantageous in that the direction of the laser may be reversed (rotated 180 degrees with respect to the normal to the mirror's main plane) such that the device projects to the right side (say) rather than to the left. For example, in an application in which a laser is oriented at an X-Z plane, with an impinging angle relative to the normal of the mirror plane (main plane), the projected image occurs on one side of the normal in FIG. 6c and on the other side of the normal in FIG. 6d.

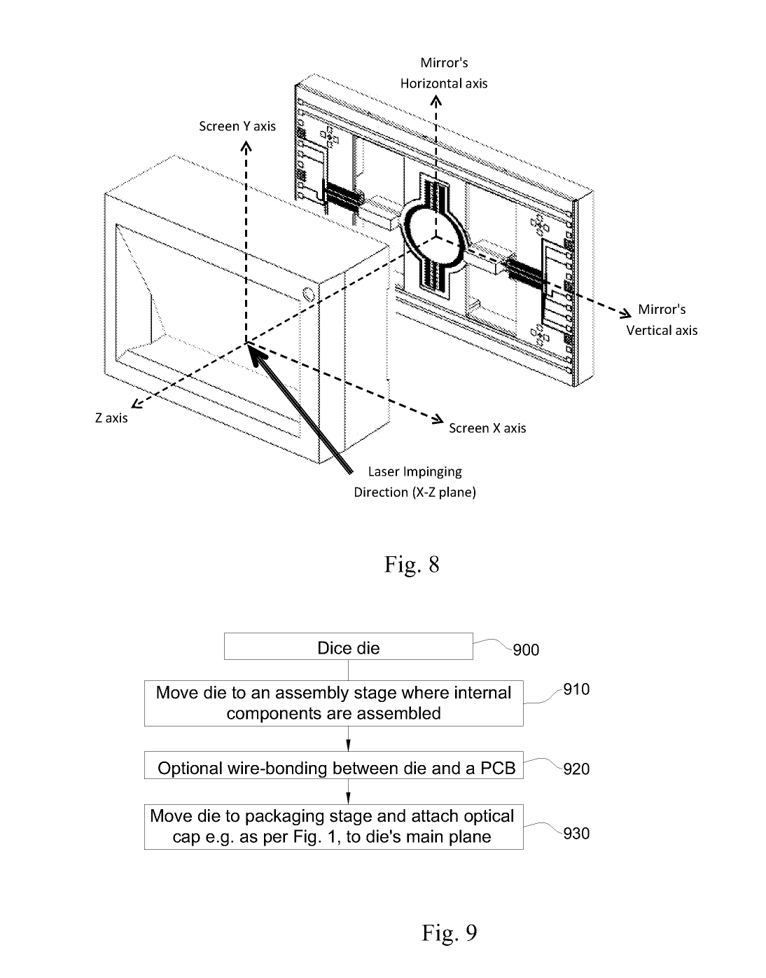

FIG. 8 is an exploded view of the apparatus of FIG. 1. Two axes of a mirror within a pico-projector assembly and orientation of the protective element with respect to the mirror, according to certain embodiments, are shown. As shown, the mirror may be oriented such that its horizontal axis is parallel to the Y axis of a screen on which images are to be projected. The mirror's vertical axis may be parallel to the X axis of the screen. The laser beam is oriented along the X-Z plane; its impinging angle measured relatively to the screen's X axis is shown. The protective element's tilted surface is tilted at an angle alpha, with respect to the X-Y plane, which is measured relatively to the screen X axis.

The direction of the reflected radiation is typically determined by the angle of the tilted optical window, whose angle is selected to direct unwarranted radiation e.g. radiation reflected from the window itself, to a location which does not affect the proper operation of the core optical device. Typically, the angle of the inclined surface of the optical window is selected to be smaller than the critical angle of the light, to ensure that most of the energy of the unwarranted radiation passes through the optical window.

The device referred to may comprise a MEMS-based mirror or other functional unit, or an entire MEMS die formed of semi-conductive materials that are used in the semiconductor industry e.g. silicone, glass, alumina, ceramics and a combination thereof.

The protective structure protects the MEMS device but the MEMS device is typically functional without it. The protective element may be made of a different material than the MEMS device—either plastic or glass.

A particular advantage of certain embodiments of the present invention is that the resulting optical system diverts ghost images, such as those generated due to reflection from the optical cap, to outside of the field of view serving the actual application for which the core optical device is designed (e.g. the field of view of a pico-projector whose core optical device comprises a scanning mirror.

A particular advantage of certain embodiments of the present invention is that the resulting optical system comprising the optical cap and the MEMS die may be manufactured using an automatic assembly process such as “pick and place”. Each optical cap may be manufactured in an individual process as described herein, and subsequently assembled using conventional MEMS assembly processes such as “pick-and-place”, wafer-level-packaging or any other process which, in order to attach or otherwise position parts formed, perhaps, of plastic, metal, or glass atop, say, a silicone die, a device such as a vacuum tip is used to grasp a particularly oriented (e.g. horizontally oriented), large enough surface of the part in question. Preferably, then, when employing the pick-and-place method, each part should have a perfectly parallel top surface rather than a tilted top surface.

A particular advantage of certain embodiments of the present invention is that the resulting optical system has both a tilted optical surface and a parallel top surface.

A particular advantage of certain embodiments is that a one-piece optical element is operative to deflect reflections out of the field of view. It is appreciated that if several prisms are employed, in state of the art systems, to deflect reflections out of the field of view, these are typically formed separately e.g. because these prisms are covered with different materials and/or require specific coatings for different prisms.

A particular advantage of certain embodiments of the present invention is provision of a triple-function protective part that:

a. encloses hence protects a MEMS device,

b. includes a tilted optical surface which diverts unwarranted electromagnetic radiation away from a field of view defined by the application for the MEMS device, and

c. includes a properly oriented top surface to facilitate use of automatic assembly processes.

This is advantageous because of the great need for (i) compact systems, for example to afford portability e.g. as in portable pico-projectors; and (ii) cost-effective manufacturing methods; if 2 or 3 parts were employed to yield the above three functions, the system would be less compact and more costly to manufacture.

A particular advantage of certain embodiments is that the protective element is cost-effective because it may be manufactured using a conventional injection molding process. This is a very low-cost process using low-cost materials and yielding large quantities of produce.

A particular advantage of certain embodiments is that the protective element is cost-effective because it may be assembled using pick-and-place technology e.g. employing SMT (surface mount technology) component placement systems operative to place a surface-mount device (SMD) onto a printed circuit board (PCB). This technique excels in high speed, high precision placing of electronic components onto PCBs which, in turn, may be incorporated into a wide variety of systems such as telecommunications equipment, consumer electronic goods, and others.

MEMS-based micro-mirrors for projection and display may be provided in either of various types of packages such as system level packaging and die level (MEMS) packaging.

System Level Packaging:

When a silicon-based component is used, it is normally just one item inside an entire system, which can include different components packed together, depending on the application. For micro-mirrors intended for projection applications, a silicon-based component may be just one item inside an entire system, which may include electronic boards and/or laser modules, optical elements such as prisms and/or lenses, and more. The MEMS itself is also a subsystem which may employ additional miniature components (e.g. magnets, coils, other) for its operation. Therefore, the package, if on the system level, may include elements in addition to the MEMS die such as driving electronics and/or a laser module.

Die Level (MEMS) Packaging

(chip to wafer or chip to chip) includes packaging of the silicon die itself as a sole component, or of the die with other components inherent to its operation. In this method, the die is diced as part of the manufacturing process. Then it is moved to an assembly stage where the internal components e.g. magnets and/or coils are assembled. Sometimes wire-bonding (electrical bonding between the die and a PCB) is performed. Finally, the die is moved to the packaging stage, where an optical cap in accordance with an embodiment of the present invention may be attached to the die's main plane, e.g. as shown in the die level (MEMS) packaging method of FIG. 9.

The dies, after dicing, are handled as part of the assembly process. One of the stages of the assembly is packing the device such that it is protected e.g. using an optical cap with a tilted surface as described herein both to overcome manufacturing challenges and to achieve diversion of the reflection of the laser outside of the FOV.

Generally, die packaging can be very low-cost, and materials chosen for the cap can vary. Wafer level packaging is more costly, since it requires another step at the silicone manufacturing process and requires packaging of the entire wafer, including malfunctioning dies. In “chip to wafer” format die level (MEMS) packaging, working dies may be selected and packed individually. It is appreciated that devices that require vacuum conditions are typically packed inside hermetic packages, usually limited to glass. In contrast, for devices operative at ambient conditions, hermetic packaging is not required.

Both in system level packaging and in die level (MEMS) packaging, a MEMS-based micro-mirror may be provided in conjunction with a light source (laser) so as to form an optical system. A ghost image reflected from the package typically arises only when the device is packaged alone, such that there is a divider medium between the light source and the mirror. When system level packaging is used, the light typically impinges upon the mirror without encountering any medium (reflected surface e.g.) so there is no reflection that needs to be diverted.

The following may be used for packaging of the device alone:
a. Ceramic packaging: A ceramic package may be used as a substrate for the micro-mirror, typically forming a parallel plane underneath the mirror plane. The ceramic package or portion thereof which covers the device is typically parallel to the mirror plane so additional optical means, e.g. prism/s, are typically employed to divert unwarranted reflection.
b. Wafer level packaging (wafer to wafer): packaging a device at wafer level (before dicing the wafers to individual dies i.e. as an alternative to packaging each one of many previously diced dies). The package is then parallel to the wafer; normally the package surface is parallel to the mirror.

One application of certain embodiments of the present invention is for a pico projector including an image projector in a handheld or portable device, such as but not limited to mobile phones, personal digital assistants, and digital cameras, or any device having enough storage for presentation materials but not for a display screen. Instead, miniaturized hardware and software, typically a single chip, may project digital images onto an available external viewing surface, such as a wall. The system typically comprises some or all of a battery, electronics converting an image to be projected into electronic signals, coherent light source/s with different colors and intensities driven by the signals, combiner optic, and scanning mirrors. In the combiner optic the different light paths are combined into one path. Then, the mirrors copy the image's pixels and project the image.

It is appreciated that terminology such as “mandatory”, “required”, “need” and “must” refer to implementation choices made within the context of a particular implementation or application described herewithin for clarity and are not intended to be limiting since in an alternative implementation, the same elements might be defined as not mandatory and not required or might even be eliminated altogether.

It is appreciated that software components of the present invention, e.g. for control of processes shown and described herein, including programs and data may, if desired, be implemented in ROM (read only memory) form including CD-ROMs, EPROMs and EEPROMs, or may be stored in any other suitable typically non-transitory computer-readable medium such as but not limited to disks of various kinds, cards of various kinds and RAMs. Components described herein as software may, alternatively, be implemented wholly or partly in hardware, if desired, using conventional techniques. Conversely, components described herein as hardware may, alternatively, be implemented wholly or partly in software, if desired, using conventional techniques.

The scope of the present invention is not limited to structures and functions specifically described herein and is also intended to include devices which have the capacity to yield a structure, or perform a function, described herein, such that even though users of the device may not use the capacity, they are if they so desire able to modify the device to obtain the structure or function.

Features of the present invention which are described in the context of separate embodiments may also be provided in combination in a single embodiment.

For example, a system embodiment is intended to include a corresponding process embodiment. Also, each system embodiment is intended to include a server-centered “view” or client centered “view”, or “view” from any other node of the system, of the entire functionality of the system, computer-readable medium, apparatus, including only those functionalities performed at that server or client or node.

Conversely, features of the invention, including method steps, which are described for brevity in the context of a single embodiment or in a certain order may be provided separately or in any suitable subcombination or in a different order. “e.g.” is used herein in the sense of a specific example which is not intended to be limiting. It is appreciated that in the description and drawings shown and described herein, functionalities described or illustrated as systems and sub-units thereof can also be provided as methods and steps therewithin, and functionalities described or illustrated as methods and steps therewithin can also be provided as systems and sub-units thereof. The scale used to illustrate various elements in the drawings is merely exemplary and/or appropriate for clarity of presentation and is not intended to be limiting.

1. A method for protecting an optical MEMS device, including:
providing an optical MEMS device, including a micro-mirror, defining a field of view and including layers which define a main plane; and
forming a protective element, constructed and operative for at least partly covering the optical MEMS device, from an optical structural material and wherein the protective element includes a planar portion tilted with respect to said main plane via which a majority of light energy directed toward said main plane must pass,
wherein the protective element also defines a top planar surface parallel to said main plane and wherein said planar portion tilted with respect to said main plane is disposed intermediate said main plane and said top planar surface,
the method also comprising placing said protective element adjacent to the optical device, subsequent to said forming,
and wherein a plurality of protective elements are manufactured one-by-one and then assembled one-by-one on a corresponding plurality of dies.

2. A method according to claim 1 wherein said protective element is configured and oriented to complete an enclosure sealing off the optical MEMS device relative to the environment.

3. (canceled)

4. A method according to claim 1 wherein:
presence of said protective element results in unwarranted reflection when the optical MEMS device is illuminated with electromagnetic radiation; and wherein
said providing a protective element comprises selecting, for the planar portion, a tilt angle, relative to the first main plane, which prevents the unwarranted reflection from entering the field of view.

5. A method according to claim 4 wherein said electromagnetic radiation is provided by a coherent light source.

6. A system for protecting an optical MEMS device, including:
an optical MEMS device, including a micro-mirror, defining a field of view and including layers which define a main plane; and
a protective element, constructed and operative for at least partly covering the optical MEMS device, from an optical structural material and wherein the protective element includes a planar portion tilted with respect to said main plane via which a majority of light energy directed toward said main plane must pass,
wherein the protective element also defines a top planar surface parallel to said main plane and wherein said planar portion tilted with respect to said main plane is disposed intermediate said main plane and said top planar surface, and
wherein said protective element comprises a one-piece optical element.

7. A method according to claim 1 wherein said forming is performed atop the optical device, which is oriented such that said main plane is horizontal.

8. A system according to claim 6 wherein said top planar surface at least partly surrounds said planar portion tilted with respect to said first main plane.

9. A system according to claim 6 wherein coherent electromagnetic radiation impinges upon said main plane thereby to define a first axis and wherein the planar portion is tilted with respect to said main plane, along a second axis perpendicular to the first axis.

10. A method according to claim 1 and also comprising applying a vacuum tip to the top planar surface parallel to said main plane.

11. A method according to claim 1 wherein said optical MEMS device is operative to project signals, representing information, through an optical window formed by said protective element.

12. A method according to claim 1 wherein said micro-mirror comprises a digital mirror moving between first and second orientations.

13. A method according to claim 1 wherein said micro-mirror comprises a scanning micro-mirror.

14. A method according to claim 1 wherein said micro-mirror comprises an analog mirror operative for continuous motion.

15. A system according to claim 6 wherein the protective element also includes a bottom planar surface attached to the MEMS device.

16. (canceled)

17. A method for protecting an optical MEMS device, including:
providing an optical MEMS device, including a micro-mirror, defining a field of view and including layers which define a main plane; and
forming a protective element, constructed and operative for at least partly covering the optical MEMS device, from an optical structural material and wherein the protective element includes a planar portion tilted with respect to said main plane via which a majority of light energy directed toward said main plane must pass,
wherein said protective element comprises a one-piece optical element,
and wherein the device is formed from a die having a main plane, the method also comprising die level (MEMS) packaging by:
dicing the die;
moving the die to an assembly stage where internal components are assembled; and moving the die to a packaging stage, where an optical cap is attached to the die's main plane.

18-19. (canceled)

20. A method according to claim 17 and also comprising placing said protective element adjacent to the optical device, subsequent to said forming.

21. A method according to claim 20 and wherein a plurality of protective elements are manufactured one-by-one and then assembled one-by-one on a corresponding plurality of dies.

22. A method according to claim 17 and wherein said protective element comprises a one-piece optical element.
